(19) United States
(12) Patent Application Publication
(10) Pub. No.: US 2026/0136890 A1
(43) Pub. Date: May 14, 2026

(54) WAFER CLEANING APPARATUS

(71) Applicant: SUMSUNG ELECTRONICS CO., LTD., Suwon-si (KR)

(72) Inventors: Jihye KANG, Suwon-si (KR); Sangsick PARK, Suwon-si (KR); Hyoungjoo LEE, Suwon-si (KR)

(73) Assignee: SUMSUNG ELECTRONICS CO., LTD., Suwon-si (KR)

(21) Appl. No.: 19/211,959

(22) Filed: May 19, 2025

(30) Foreign Application Priority Data
Nov. 8, 2024 (KR) 10-2024-0157825

(51) Int. Cl. H01L 21/687; H01L 21/67

(52) U.S. Cl. CPC H10P 72/7624; H10P 72/0414

(57) ABSTRACT

A wafer cleaning device includes a rotary table that rotate around a rotation axis, and includes a mounting surface having one or more disposition regions spaced apart from the rotation axis, the mounting surface being disposed downwardly, and a cleaning fluid supply disposed below and opposite to the mounting surface and supplying a cleaning fluid upwardly to the one or more disposition regions.

### CROSS-REFERENCE TO RELATED APPLICATION

This application is based on and claims priority to Korean Patent Application No. 10-2024-0157825, filed on Nov. 8, 2024 in the Korean Intellectual Property Office, the contents of which being incorporated by reference herein in its entirety.

### BACKGROUND

The present disclosure relates to a wafer cleaning apparatus.

In a wafer manufacturing process, a cleaning device is used to remove various foreign substances attached to a wafer. For example, in a wafer bonding process, a chip-on-wafer bonding reflow process using flux is performed to mount a chip on the wafer, and then a cleaning process for removing foreign substances such as flux residues on the wafer may be performed using the cleaning device.

In such a cleaning process, when cleaning a wafer using a cleaning fluid, there is a risk that the cleaning fluid after cleaning may splash back onto the wafer, causing the wafer to be re-contaminated. Therefore, a cleaning device that can effectively clean the wafer is required.

### SUMMARY

It is an aspect to provide a wafer cleaning device that can effectively clean a wafer.

According to an aspect of one or more embodiments, there is a wafer cleaning device comprising a rotary table configured rotate around a rotation axis, and including a mounting surface having at least one disposition region that is spaced apart from the rotation axis, the mounting surface being disposed downwardly; and a cleaning fluid supply disposed below and opposite to the mounting surface and supplying a cleaning fluid upwardly to the at least one disposition region.

According to another aspect of one or more embodiments, there is a wafer cleaning device comprising a rotary table configured to rotate around a rotation axis, and including a mounting surface that has a plurality of disposition regions that are spaced apart from the rotation axis, wherein the mounting surface is disposed downwardly; a plurality of chucks disposed respectively in the plurality of disposition regions, each of the plurality of chucks including a holding surface configured to adsorb and hold a wafer and a plurality of position limiting pins disposed to be elevatable on the holding surface for position limiting or releasing the position limiting of an outer peripheral surface of the wafer; and a cleaning fluid supply disposed below and opposite to the mounting surface and supplying a cleaning fluid upwardly to the plurality of disposition regions.

According to yet another aspect of one or more embodiments, there is a wafer cleaning device comprising a chamber including a processing space for processing a wafer; a rotary shaft rotatably disposed above the processing space around a rotation axis; a rotary driver connected to the rotary shaft and configured to rotate the rotary shaft; a rotary table disposed below the rotary shaft, and including a mounting surface has a plurality of disposition regions that are spaced apart from the rotation axis, the mounting surface being disposed downwardly; a cleaning fluid supply disposed below the processing space and supplying a cleaning fluid upwardly to the plurality of disposition regions; and a discharge device that discharges the cleaning fluid within the processing space.

### BRIEF DESCRIPTION OF DRAWINGS

The above and other aspects will be more clearly understood from the following detailed description, taken in conjunction with the accompanying drawings, in which:

FIG. 1 is an exemplary diagram illustrating a wafer cleaning device according to an example embodiment;

FIG. 2 is an exemplary diagram illustrating a rotary table and a cleaning fluid supply in the wafer cleaning device of FIG. 1, according to an example embodiment;

FIG. 3 is an exemplary drawing illustrating a mounting surface of the rotary table in the wafer cleaning device of FIG. 1, according to an example embodiment;

FIG. 4 is an exemplary drawing illustrating a wafer cleaning device according to an example embodiment;

FIG. 5 is an exemplary drawing illustrating a rotary table and a cleaning fluid supply in the wafer cleaning device of FIG. 4, according to an example embodiment;

FIG. 6 is an exemplary drawing illustrating a mounting surface of the rotary table in the wafer cleaning device of FIG. 4, according to an example embodiment;

FIG. 7 is an exemplary diagram illustrating a wafer cleaning device according to an example embodiment;

FIG. 8 is an exemplary diagram illustrating a mounting surface of a rotary table in the wafer cleaning device of FIG. 7, according to an example embodiment; and

FIG. 9 is an exemplary diagram illustrating a wafer cleaning device according to an example embodiment.

### DETAILED DESCRIPTION

Hereinafter, various example embodiments will be described with reference to the attached drawings.

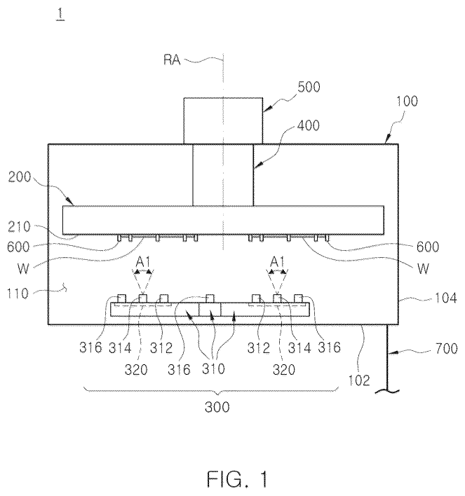

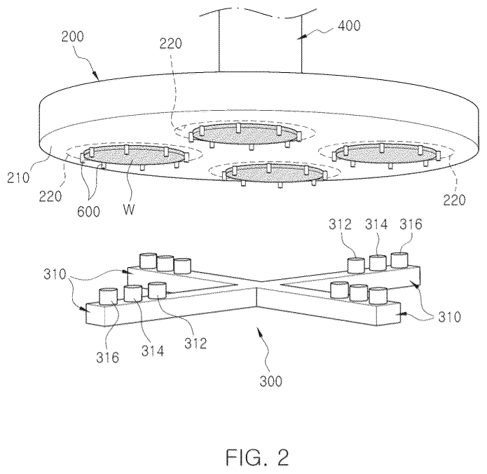

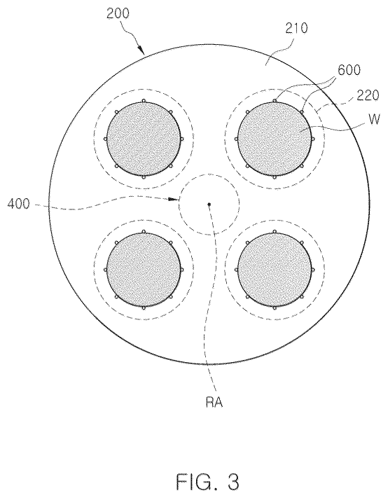

FIG. 1 is an exemplary diagram illustrating a wafer cleaning device according to an example embodiment, FIG. 2 is an exemplary diagram illustrating a rotary table and a cleaning fluid supply in the wafer cleaning device of FIG. 1, according to an example embodiment, and FIG. 3 is an exemplary diagram illustrating a mounting surface of a rotary table in the wafer cleaning device of FIG. 1, according to an example embodiment.

Referring to FIGS. 1 to 3, a wafer cleaning device 1 may include a chamber 100, a rotary table 200, and a cleaning fluid supply 300.

The chamber 100 may include a processing space 110 for processing a wafer W therein. The wafer W may be cleaned in the processing space 110 of the chamber 100. In an example embodiment, a wafer W onto which various chips are bonded may be cleaned in the processing space 110 of the chamber 100. However, example embodiments are not limited thereto, and in some example embodiments, a wafer having completed various process processes may be cleaned. An entrance for loading and unloading the wafer may be disposed in the chamber 100.

The rotary table 200 may be rotatably disposed above the processing space 110 of the chamber 100 by a rotary shaft 400. The rotary shaft 400 may have a rotation axis RA. The rotation axis RA may be disposed in a vertical direction. The rotary shaft 400 may be disposed to be rotatable around the rotation axis RA above the processing space 110 of the chamber 100 together with the rotary table 200. The rotary shaft 400 may be a portion of the rotary table 200. A rotary driver 500 providing rotational force to the rotary shaft 400 may be disposed on the rotary shaft 400. The rotary driver 500 may include a driving motor. In an example embodiment, the rotary driver 500 may be provided with a power transmission structure that transmits power between the driving motor and the rotary shaft 400.

The rotary table 200 may be disposed below the rotary shaft 400. The rotary table 200 may be configured to be rotatable around the rotation axis RA. The rotary table 200 may rotate around the rotation axis RA together with the rotary shaft 400. The rotary table 200 may be formed in a plate shape such as a disk shape, but example embodiments thereof are not limited thereto. The rotary table 200 may include a mounting surface 210. The mounting surface 210 may be disposed downwardly. Here, the phrase “disposed downwardly” denotes that the mounting surface 210 is disposed to face the cleaning fluid supply 300, as illustrated in FIG. 1. The mounting surface 210 of the rotary table 200 may be disposed as a lower surface of the rotary table 200 opposite to the cleaning fluid supply 300. An upper surface of the rotary table 200 is disposed opposite to an upper end of the processing space 110 of the chamber 100 and may be connected to the rotary shaft 400. As best seen in FIG. 2, the mounting surface 210 may include at least one disposition region 220 in which a wafer (W) is disposed, and the at least one disposition region 220 may be disposed on the mounting surface 210 of the rotary table 200. In an example embodiment, a plurality of disposition regions 220 in which a wafer (W) is disposed may be disposed on the mounting surface 210 of the rotary table 200. The plurality of the disposition regions 220 may be disposed to be spaced apart from the rotation axis (RA) at equal intervals on the mounting surface 210 of the rotary table 200, as best seen in FIG. 3. The plurality of the disposition regions 220 may be disposed to be spaced apart from the rotation axis (RA) at equal intervals. A center portion of each of the plurality of the disposition regions 220 may be disposed on a same circle with the rotation axis (RA) as a centrifuge on the mounting surface 210 of the rotary table 200. An interval between the plurality of disposition regions 220 in a circumferential direction (i.e., on the same circle) may be the same.

Each of the disposition regions 220 may include a plurality of position limiting pins 600 for position limiting and releasing the position limiting of the wafer (W). The plurality of position limiting pins 600 may be configured to be elevatable in each of the disposition regions 220. The plurality of position limiting pins 600 may be configured to hold an outer peripheral surface of the wafer (W) to limit the position of the wafer (W) or release the holding to release the limit of the position of the wafer (W).

In an example embodiment, as shown in FIGS. 1 to 3, four disposition regions 220 in which wafers (W) may be respectively disposed may be disposed on the mounting surface 210 of the rotary table 200, but example embodiments are not limited thereto. One, two, three, or five or more disposition regions may be disposed on the mounting surface of the rotary table. In the embodiment illustrated in FIGS. 1-3, an example is described in which four disposition regions 220 are disposed on the mounting surface 210 of the rotary table 200. Each of the disposition regions 220 may be spaced apart from the rotation axis (RA) on the mounting surface 210 of the rotary table 200. Accordingly, each of the disposition regions 220 is disposed eccentrically with respect to the rotation axis (RA) on the mounting surface 210 of the rotary table 200, so that wafers (W) disposed in each of the disposition regions 220 may be eccentrically rotated in the process in which the rotary table 200 rotates around the rotation axis (RA) by the rotary shaft 400.

The cleaning fluid supply 300 may be disposed below the processing space 110 of the chamber 100. The cleaning fluid supply 300 may be disposed below and opposite to the mounting surface 210 of the rotary table 200 and may supply a cleaning fluid upwardly to the disposition region 220. The cleaning fluid supply 300 may supply a cleaning fluid upwardly toward the mounting surface 210 of the rotary table 200. The cleaning fluid may be a cleaning liquid or a cleaning gas. In an example embodiment, the cleaning fluid may be a cleaning liquid such as deionized water (DIW), isopropyl alcohol (IPA), DHF, SC, or a cleaning gas such as N gas, but example embodiments are not limited thereto and in some example embodiments, the cleaning fluid may be various other cleaning liquids or cleaning gases. In an example embodiment, the cleaning fluid may be ultrapure water. In a state in which the wafer (W) is disposed and fixed in each disposition region 220 of the rotary table 200 and then the rotary table 200 is rotated, the cleaning fluid supply 300 may spray a cleaning fluid toward each disposition region 220 to clean the wafer (W). In the cleaning process, each wafer (W) is not disposed on a portion of the rotation axis in which cleaning power is weak due to a rotation speed thereof in the rotary table 200, but is disposed in a disposition region 220 spaced apart from the rotation axis (RA) of the rotary shaft 400 of the rotary table 200 and rotates eccentrically, so that the cleaning power may be further strengthened for an inner portion of the wafer (W), which is relatively close to the rotation axis (RA), thereby improving the cleaning efficiency for each wafer (W).

In the related art technology in which a cleaning process is performed above the wafer, a direction in which the cleaning fluid is sprayed is the same as a direction in which the cleaning fluid flows downwardly after the cleaning process, so there is a risk that the cleaning fluid having cleaned the wafer may hit an upper portion of the inner wall of the chamber, flow down, and splash back onto the wafer, thereby causing the wafer to be re-contaminated. However, by contrast, in the example embodiment described with respect to FIGS. 1-3, since the wafer is fixed in the disposition region 220 disposed on the mounting surface 210, which is a lower surface of the rotary table 200 and cleaned by spraying the cleaning fluid upward from below by the cleaning fluid supply 300, the cleaning fluid that has been cleaned flows downwardly, unlike the direction in which the cleaning fluid is sprayed upwardly, so that re-contamination of the wafer (W) can be effectively prevented.

As shown in FIGS. 1 and 3, the cleaning fluid supply 300 may include a plurality of spray nozzle assemblies 310. The plurality of spray nozzle assemblies 310 may be disposed opposite to each of the disposition regions 220 as best seen in FIG. 2 and may spray the cleaning fluid upward toward each of the corresponding disposition regions 220. In an example embodiment, the plurality of spray nozzle assemblies 310 may be configured to be integrated or assembled as shown in FIGS. 1 and 2, but example embodiments are not limited thereto, and in some example embodiments, the plurality of spray nozzle assemblies 310 may respectively be independently disposed in the processing space 110 of the chamber 100. Each of the plurality of spray nozzle assemblies 310 may include a plurality of spray nozzles 312, 314, and 316. The plurality of spray nozzles 312, 314, and 316 of each of the spray nozzle assemblies 310 may be disposed in one direction parallel to the mounting surface 210 of the rotary table 200. For example, in an example embodiment, the plurality of spray nozzles 312, 314, and 316 may be disposed in a radial direction.

Each of the plurality of spray nozzles 312, 314, and 316 of the spray nozzle assembly 310 can spray various cleaning fluids. In an example embodiment, each of the plurality of spray nozzles 312, 314, and 316 of the spray nozzle assembly 310 may spray the same cleaning liquid. In another example embodiment, each of the plurality of spray nozzles 312, 314, and 316 of the spray nozzle assembly 310 may spray different cleaning liquids.

In an example embodiment, the cleaning fluid supply 300 may include an angle adjustment device 320 connected to each of the spray nozzle assemblies 310. The angle adjustment device 320 may adjust a spraying angle (A1) of each of the spray nozzle assemblies 310. The angle adjustment device 320 may control a spraying direction of the cleaning fluid toward the wafer (W) disposed in each disposition region 220 of the rotary table 200 by adjusting the spraying angle (A1) of the plurality of spray nozzles 312, 314, and 316 of each spray nozzle assembly 310, thereby completely removing various foreign substances on the wafer (W). The angle adjustment device 320 may be formed in various forms. In an example embodiment, the spraying angle (A1) of the plurality of spray nozzles 312, 314, and 316 may be adjusted by adjusting an angle of an installation direction of each spray nozzle assembly 310, or the spraying angle (A1) of each of the plurality of spray nozzles 312, 314, and 316 of each spray nozzle assembly 310 may be rotatably disposed so that the spraying angle (A1) of each of the plurality of spray nozzles 312, 314, and 316 can be independently adjusted. Each spray nozzle assembly 310 may be movably disposed in the processing space 110 of the chamber 100. In FIGS. 1 to 3, each spray nozzle assembly 310 may include three spray nozzles 312, 314, and 316, but example embodiments are not limited thereto, and in some example embodiments may include one, two, four, or more spray nozzles.

The wafer cleaning device according to an example embodiment may further include a discharge device 700 for discharging the cleaning fluid within the processing space 110 of the chamber 100. The discharge device 700 may be a drain and/or a pipe that is disposed on a lower wall 102 or a side wall 104 of the chamber 100. In an example embodiment, as illustrated in FIG. 1, the discharge device 700 may be disposed on the lower wall 102 of the chamber 100.

The wafer cleaning device according to the example embodiment illustrated with respect to FIGS. 1-3 above may effectively clean a wafer (W) and prevent re-contamination of the wafer (W) due to re-attachment of the cleaning fluid.

In the above, it is illustrated that a wafer is directly disposed on a disposition region of a mounting surface of a rotary table, but example embodiments are not limited thereto, and the wafer may be indirectly disposed on the disposition region of the mounting surface of the rotary table. Hereinafter, indirectly disposing a wafer on a disposition region of a rotary table will be described.

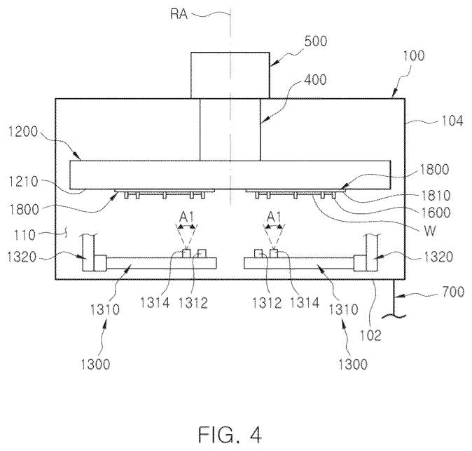

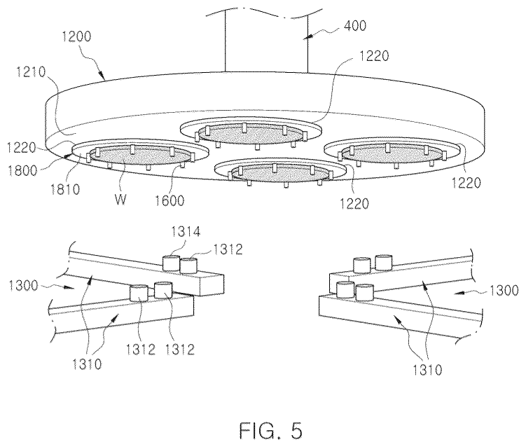

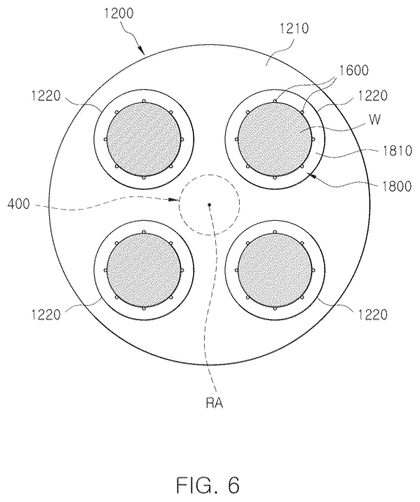

FIG. 4 is an exemplary diagram illustrating a wafer cleaning device according to an example embodiment, FIG. 5 is an exemplary diagram illustrating a rotary table and a cleaning fluid supply in the wafer cleaning device of FIG. 4, according to an example embodiment, and FIG. 6 is an exemplary diagram illustrating a mounting surface of the rotary table in the wafer cleaning device of FIG. 4, according to an example embodiment.

Referring to FIGS. 4 to 6, a wafer cleaning device according to FIGS. 4-6 may include a chamber 100, a rotary table 1200, a cleaning fluid supply 1300, a rotary shaft 400, a rotary driver 500, a position limiting pin 1600, a discharge device 700, and a chuck 1800. The configuration of the chamber 100, the rotary shaft 400, the rotation driving device 500, and the discharge device 700, except for the configuration of the rotary table 1200, the cleaning fluid supply 1300, the position limiting pin 1600, and the chuck 1800 may be implemented in the same manner as the configuration of the chamber 100, the rotary shaft 400, the rotary driving device 500, and the discharge device 700 described above, and a duplicate description thereof is omitted for conciseness.

The rotary table 1200 may be rotatably disposed above the processing space 110 of the chamber 100 by the rotary shaft 400. The rotary table 1200 may be disposed below the rotary shaft 400. The rotary table 1200 may rotate around the rotation axis (RA) together with the rotary shaft 400. The rotary shaft 400 may be rotatably disposed around the rotation axis (RA) above the processing space 110 of the chamber 100 together with the rotary table 1200 by a rotary driver 500 connected to the rotary shaft 400.

The rotary table 1200 may be formed in a plate shape such as a disk shape, but example embodiments are not limited thereto. The rotary table 1200 may include mounting surface 1210, disposed downwardly. The mounting surface 1210 of the rotary table 1200 may be disposed as a lower surface of the rotary table 1200 and opposite to the cleaning fluid supply 1300. An upper surface of the rotary table 1200 may be disposed opposite to an upper end of the processing space 110 of the chamber 100 and may be connected to the rotary shaft 400. At least one disposition region 1220 in which a wafer (W) is disposed may be disposed on the mounting surface 1210 of the rotary table 1200. In an example embodiment, a plurality of disposition regions 1220 in which a wafer (W) is disposed may be disposed on the mounting surface 1210 of the rotary table 1200. The plurality of disposition regions 1220 may be disposed to be spaced apart from the rotation axis (RA) at equal intervals on the mounting surface 1210 of the rotary table 1200. The plurality of disposition regions 1220 may be disposed to be spaced apart from the rotation axis (RA) at equal intervals. A center portion of the plurality of disposition regions 1220 may be disposed in a circumferential direction on a same circle with the rotation axis (RA) as a centrifuge on the mounting surface 1210 of the rotary table 1200. An interval between the plurality of disposition regions 1220 in the circumferential direction may be the same. As shown in FIGS. 4 to 6 in an example embodiment, four disposition regions 1220 may be disposed on the mounting surface 1210 of the rotary table 1200, but example embodiments are not limited thereto, and in some example embodiments, two, three, or five or more disposition regions may be disposed on the mounting surface of the rotary table. In the embodiment illustrated in FIGS. 4-6, an example is described in which four disposition regions 1220 are disposed on the mounting surface 1210 of the rotary table 1200. Each of the disposition regions 1220 may be spaced apart from the rotation axis (RA) on the mounting surface 1210 of the rotary table 1200. Accordingly, each disposition region 1220 is disposed eccentrically with respect to the rotation axis (RA) on the mounting surface 1210 of the rotary table 1200, and thus, in the process of the rotary table 1200 rotating around the rotation axis (RA) by the rotary shaft 400, the wafers (W) disposed in each disposition region 1220 may be eccentrically rotated. The wafers (W) may be disposed in each disposition region 1220 through the chuck 1800.

The wafer cleaning device according to an example embodiment may include a plurality of chucks 1800 disposed respectively in the disposition regions 1220. In other words, each of the disposition regions 1220 may have a corresponding chuck 1800. Each of the plurality of chucks 1800 may include a holding surface 1810 and a plurality of position limiting pins 1600. The holding surface 1810 may adsorb a wafer (W) and hold the wafer (W) to prevent the wafer (W) from being detached during a rotation process of the rotary table 1200. In an example embodiment, each of the plurality of chucks 1800 may be implemented as a vacuum chuck that adsorbs the wafer (W) by vacuum, and the wafer (W) may be adsorbed and held on the holding surface 1810 by the vacuum adsorption of the vacuum chuck. In some example embodiments, each of the plurality of chucks 1800 may be implemented as an electrostatic chuck that electrostatically adsorbs a wafer (W), and the wafer (W) may be adsorbed and held on the holding surface 1810 by electrostatic adsorption of the electrostatic chuck. The holding surface 1810 of each of the plurality of chucks 1800 may be disposed in a direction parallel to the mounting surface 1210 of the rotary table 1200. Accordingly, each chuck 1800 may hold the wafer (W) horizontally on the holding surface 1810. The plurality of position limiting pins 1600 may be disposed on the holding surface 1810 and may be elevatable on the holding surface 1810 of each chuck 1800. The plurality of position limiting pins 1600 may hold an outer peripheral surface of the wafer (W) to limit the position of the wafer (W) to the holding surface 1810, or release the holding of the outer peripheral surface of the wafer (W) to release the limit of the position of the wafer (W) from the holding surface 1810. Accordingly, the wafer (W) may be stably held in a double fixing method using a vacuum or electrostatic adsorption method and a fixing method of a position limiting pin 1600 through a chuck 1800 disposed in each disposition region 1220 of the rotary table 1200. During the rotation process of the rotary table 1200, the wafer (W) can be effectively prevented from being detached from the holding surface 1810 of the chuck 1800.

The cleaning fluid supply 1300 may be disposed below the processing space 110 of the chamber 100. The cleaning fluid supply 1300 may be disposed below and opposite to the mounting surface 1210 of the rotary table 1200 and may supply a cleaning fluid upwardly toward the disposition region 1220. The cleaning fluid supply 1300 may supply a cleaning fluid upwardly toward the mounting surface 1210 of the rotary table 1200. The cleaning fluid may be a cleaning liquid or a cleaning gas. In an example embodiment, the cleaning fluid may be a cleaning liquid such as deionized water (DIW), isopropyl alcohol (IPA), DHF, SC, or a cleaning gas such as N₂ gas, but example embodiments are not limited thereto and in some example embodiments may be various other cleaning liquids or cleaning gases. In an example embodiment, the cleaning fluid may include a cleaning liquid and a cleaning fluid. After the wafer (W) is disposed and fixed on a chuck 1800 disposed in a disposition region 1220 of the rotary table 1200, the cleaning fluid supply 1300 may spray cleaning liquid or cleaning gas toward each disposition region 1220 while the rotary table 1200 is rotating to clean the wafer (W). In the cleaning process, each wafer (W) is eccentrically disposed on a chuck 1800 disposed in a disposition region 1220, spaced apart from the rotation axis (RA) of the rotary shaft 400 of the rotary table 1200, so that the cleaning power may be further strengthened for an inner portion of the wafer (W) which is relatively close to the rotation axis (RA), thereby improving the cleaning efficiency for each wafer (W).

As shown in FIGS. 4 and 5, the cleaning fluid supply 1300 may include a plurality of spray nozzle assemblies 1310. The plurality of spray nozzle assemblies 1310 may be disposed opposite to the disposition regions 1220 and may spray the cleaning fluid toward the disposition regions 1220. Each of the spray nozzle assemblies 1310 may include a spray nozzle for spraying a cleaning liquid and/or a cleaning gas. In an example embodiment, as illustrated in FIGS. 4 and 5, the spray nozzle assembly 1310 may include a first spray nozzle 1312 spraying a cleaning liquid and a second spray nozzle 1314 spraying a cleaning gas. Accordingly, depending on the process, one of the first spray nozzle 1312 and the second spray nozzle 1314 may be selected to perform a cleaning treatment on the wafer (W). The first spray nozzle 1312 and the second spray nozzle 1314 of each of the spray nozzle assemblies 1310 may be arranged in one direction parallel to the mounting surface 1210 of the rotary table 1200, but example embodiments are not limited thereto, and in some example embodiments may be disposed in various dispositional forms.

In an example embodiment, the cleaning fluid supply 1300 may include an adjustment device 1320 connected to each of the spray nozzle assemblies 1310. The adjustment device 1320 may adjust a spray angle (A1) of each of the spray nozzle assemblies 1310. The adjustment device may control a spraying direction of the cleaning liquid and cleaning gas toward the wafer (W) disposed on the chuck 1800 on each disposition region 1220 of the rotary table 1200 by adjusting a spraying angle (A1) of the first spray nozzle 1312 and the second spray nozzle 1314 of each spray nozzle assembly 1310, thereby completely removing various foreign substances on the wafer (W). The adjustment device may adjust the position of each spray nozzle assembly 1310 in the horizontal and/or vertical positions. The adjustment device can be formed in various forms. In an example embodiment, the adjustment device 1320 may adjust the spray angle (A1) of the first spray nozzle 1312 and the second spray nozzle 1314 by adjusting an angle of an installation direction of each spray nozzle assembly 1310, or the first spray nozzle 1312 and the second spray nozzle 1314 of each spray nozzle assembly 1310 may be rotatably disposed so that the spray angle (A1) of each of the first spray nozzle 1312 and the second spray nozzle 1314 can be independently adjusted.

As shown in FIGS. 4 and 5 above, each of the plurality of spray nozzle assemblies 1310 is illustrated as including one first spray nozzle 1312, but example embodiments are not limited thereto, and in some example embodiments may include two or more first spray nozzles. In this case, each spray nozzle assembly 1310 may have a plurality of first spray nozzles for spraying various cleaning liquids. In an example embodiment, each of the plurality of first spray nozzles of the spray nozzle assembly may spray the same cleaning liquid. In another example embodiment, each of the plurality of first spray nozzles of the spray nozzle assembly may spray different cleaning liquids. As illustrated in FIGS. 4 and 5, each of the plurality of spray nozzle assemblies 1310 is illustrated as including one second spray nozzle 1314, but example embodiments are not limited thereto and in some example embodiments may include two or more second spray nozzles. In this case, each spray nozzle assembly may have a plurality of second spray nozzles for spraying various cleaning gases. In this case, each spray nozzle assembly may have a plurality of second spray nozzles for spraying various cleaning gases. In another example embodiment, each of the plurality of second spray nozzles of the spray nozzle assembly may spray different cleaning gases.

In the example embodiment described above with respect to FIGS. 4-6, it is described that a first spray nozzle and a second spray nozzle are combined and included in the same spray nozzle assembly, but example embodiments are not limited thereto, and hereinafter, an example in which the first spray nozzle and the second spray nozzle are separated and included in a separate spray nozzle assembly is described.

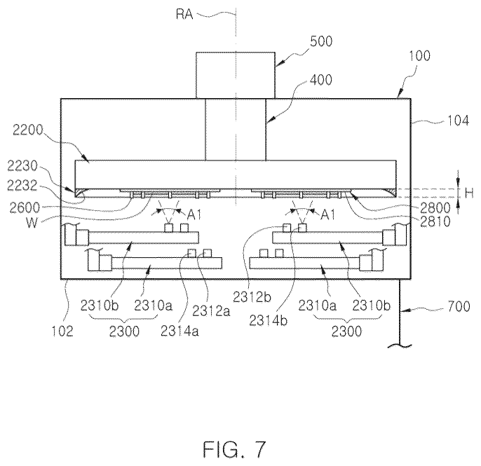

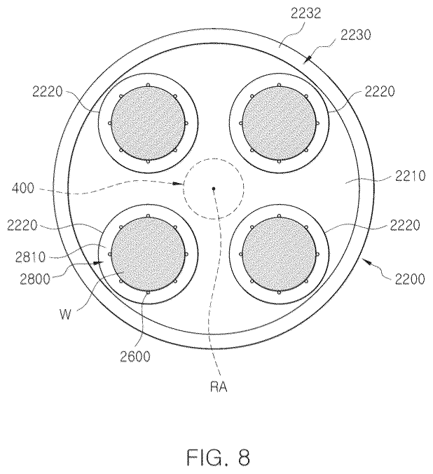

FIG. 7 is an exemplary diagram illustrating a wafer cleaning device according to an example embodiment, and FIG. 8 is an exemplary diagram illustrating a mounting surface of a rotary table in the wafer cleaning device of FIG. 7, according to an example embodiment.

Referring to FIGS. 7 and 8, a wafer cleaning device according to an example embodiment may include a chamber 100, a rotary table 2200, a cleaning fluid supply 2300, a rotary shaft 400, a rotary driver 500, a position limiting pin 2600, a discharge device 700, and a chuck 2800. The configuration of the chamber 100, the rotary shaft 400, the rotary driver 500, the position limiting pin 2600, the discharge device 700, and the chuck 2800, except for the configuration of the rotary table 2200 and the cleaning fluid supply 2300 may be implemented in the same manner as the configuration of the chamber 100, the rotary shaft 400, the rotary driver 500, the position limiting pin 1600, the discharge device 700, and the chuck 1800 described above, and a duplicate description thereof is omitted for conciseness.

The rotary table 2200 may have a guide protrusion 2230 disposed on an outer edge of the mounting surface 2210. The guide protrusion 2230 may guide the flow of the cleaning fluid so that the cleaning fluid supplied from the cleaning fluid supply 2300 upward to the wafer W on the outer edge of the mounting surface 2210 flows downwardly while cleaning the wafer W to the outer edge of the mounting surface 2210.

The guide protrusion 2230 may be implemented in various forms. In an example embodiment, the guide protrusion 2230 may be disposed in a ring shape in a circumferential direction on the outer edge of the mounting surface 2210. The guide protrusion 2230 may have a protrusion height (H) that gradually increases in an outward direction of the rotary table 2200. In an example embodiment, the protrusion height (H) of the guide protrusion 2230 may be set to be greater than a height between the holding surface 2810 of the chuck 2800 and the mounting surface 2210 of the rotary table 2200. The height between the holding surface 2810 of the chuck 2800 and the mounting surface 2210 of the rotary table 2200 may be set to O or greater than O. The guide protrusion 2230 may include a guide surface 2232 having a concavely curved shape in the outward direction of the rotary table 2200. Since the cleaning fluid that has cleaned the wafer W is guided downwardly when the cleaning fluid flows from the mounting surface 2210 of the rotary table 2200 to the outer edge by a structure of the guide protrusion 2230, re-contamination of the wafer W may be effectively prevented, and in particular, re-contamination of the cleaning fluid on the wafer W due to collision between the cleaning fluid and an inner wall of the chamber 100 may be prevented.

The cleaning fluid supply 2300 may include a plurality of spray nozzle assemblies. In an example embodiment, the cleaning fluid supply 2300 may include a plurality of first spray nozzle assemblies 2310a and a plurality of second spray nozzle assemblies 2310b disposed below and opposite to the plurality of disposition regions 2200, respectively. Each of the plurality of first spray nozzle assemblies 2310a may include at least one first spray nozzle (2312a, 2314a) for spraying a cleaning liquid. Each of the plurality of second spray nozzle assemblies 2310b may include a plurality of second spray nozzles 2312b and 2314b) for spraying a cleaning gas. That is, one first spray nozzle assembly 2310a and one second spray nozzle assembly 2310b may be combined as a pair and disposed opposite to each of the disposition regions 2200 and may spray the cleaning fluid toward each of the disposition regions 2200. The first spray nozzles 2312a and 2314a of each of the first spray nozzle assemblies 2310a may spray the same cleaning fluid, but example embodiments are not limited thereto and in some example embodiments may spray different cleaning fluids. The second spray nozzles 2312b and 2314b of each of the second spray nozzle assemblies 2310b may spray the same cleaning fluid, but example embodiments are not limited thereto and in some example embodiments may spray different cleaning fluids. The first spray nozzles 2312a and 2314a and the second spray nozzles 2312b and 2314b may spray different cleaning fluids. In an example embodiment, the first spray nozzles 2312a and 2314a may spray a cleaning liquid, and the second spray nozzles 2312b and 2314b may spray a cleaning gas. Therefore, depending on the process, the first spray nozzle assembly 2310a or the second spray nozzle assembly 2310b may be selectively used to perform a cleaning process on the wafer (W). In another example embodiment, the first spray nozzles 2312a and 2314a may spray a cleaning liquid, and the second spray nozzles 2312b and 2314b may spray a cleaning liquid different from the first spray nozzles 2312a and 2314a.

In an example embodiment, the cleaning fluid supply 2300 may include a first adjustment device 2320a connected to each of the first spray nozzle assemblies 2310a and a second adjustment device 2320b connected to each of the second spray nozzle assemblies 2310b.

The first adjustment device 2320a may adjust a spray angle (A1) of the first spray nozzle assembly 2310a. The first adjustment device 2320a may control a spray direction of a cleaning fluid toward the wafer (W) disposed on the chuck 2800 on each disposition region 2220 of the rotary table 2200 by adjusting the spray angle (A1) of the first spray nozzles 2312a and 2314a of the first spray nozzle assembly 2310a, thereby completely removing various foreign substances on the wafer (W). The first adjustment device 2320a may adjust a position of each first spray nozzle assembly 2310a in the horizontal and/or vertical directions. The first adjustment device 2320a may be formed in various forms. In an example embodiment, the first adjusting device 2320a may adjust the spray angle (A1) of each of the first spray nozzles 2312a and 2314a together by adjusting an angle of an installation direction of each first spray nozzle assembly 2310a, or the spray angle (A1) of each of the first spray nozzles 2312a and 2314a may be rotatably disposed so that the spray angle (A1) of each of the first spray nozzles 2312a and 2314a may be adjusted independently.

The second adjustment device 2320b may adjust a spray angle (A1) of the second spray nozzle assembly 2310b. The second adjustment device 2320b may control a spray direction of a cleaning fluid toward the wafer (W) disposed on the chuck 2800 on each disposition region 2220 of the rotary table 2200 by adjusting the spray angle (A1) of the second spray nozzles 2312b and 2314b of the second spray nozzle assembly 2310b, thereby completely removing various foreign substances on the wafer (W). The second adjustment device 2320b may also adjust a position of each second spray nozzle assembly 2310b in the horizontal and/or vertical directions. The second adjustment device 2320b may be formed in various forms. In an example embodiment, the second adjusting device 2320b may adjust the spray angle (A1) of each of the second spray nozzles 2312b and 2314b together by adjusting an angle of an installation direction of each second spray nozzle assembly 2310b, or the spray angle (A1) of each of the second spray nozzles 2312b and 2314b may be rotatably disposed so that the spray angle (A1) of each of the second spray nozzles 2312b and 2314b may be adjusted independently.

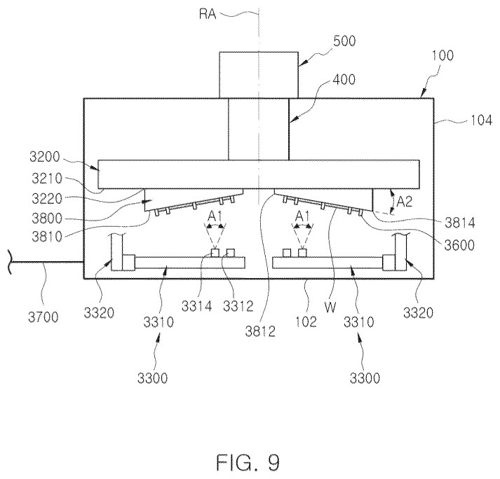

In the example embodiments described above with respect to FIGS. 4-8, it is illustrated that the chuck has a holding surface disposed horizontally to the mounting surface of the rotary table. However, example embodiments are not limited thereto, and in some example embodiments, the holding surface of the chuck may be disposed in a form that is not horizontal to the mounting surface of the rotary table, which will be described with reference to FIG. 9 below.

FIG. 9 is an exemplary diagram illustrating a wafer cleaning device according to an example embodiment.

Referring to FIG. 9, a wafer cleaning device according tan example embodiment may include a chamber 100, a rotary table 3200, a cleaning fluid supply 3300, a rotary shaft 400, a rotary driver 500, a position limiting pin 3600, a discharge device 3700, and a chuck 3800. The configuration of the chamber 100, the rotary table 3200, the cleaning fluid supply 3300, the rotary shaft 400, the rotary driver 500, and the position limiting pin 3600, except for the configuration of the discharge device 3700 and the chuck 3800 may be implemented in the same manner as the configuration of the chamber 100, the rotary table 2200, the cleaning fluid supply 2300, the rotary shaft 400, the rotary driver 500, and the position limiting pin 2600 described above, and a duplicate description thereof is omitted for conciseness.

The discharge device 3700 may include a drain and/or a pipe and may discharge the cleaning fluid within the processing space 110 of the chamber 100. The discharge 3700 may be disposed on a sidewall 104 of the chamber 100, and the cleaning fluid sprayed from the cleaning fluid supply 3300 toward a disposition region 3220 of the rotary table 3200 may discharge the processed cleaning fluid externally after cleaning the wafer W.

A holding surface 3810 of each of the plurality of chucks 3800 disposed in the disposition region 3220 of the rotary table 3200 may be disposed to be inclined at a certain angle A2 in a direction parallel to the mounting surface 3210 of the rotary table 3200. The holding surface 3810 of each of the plurality of chucks 3800 may be disposed to be inclined downwardly at a certain angle A2 with respect to a direction parallel to the mounting surface 3210 outwardly of a radial direction of the rotary table 3200. In an example embodiment, the certain angle A2 may be, but is not limited to, 0° to about 30°. The holding surface 3810 of each of the plurality of chucks 3800 may be disposed such that an inner edge portion 3812 relatively close to the rotation axis (RA) is disposed on a higher level in a horizontal direction from a lower wall 102 of the chamber 100 than an outer edge portion 3814 farther from the rotation axis (RA). Depending on the configuration of the holding surface 3810 of the inclined chuck 3800, when the cleaning fluid having cleaned a wafer W flows from the inner edge portion 3812 to the outer edge portion 3814 of the holding surface 3810 of the chuck 3800, a downwardly guiding effect can be generated, thereby effectively preventing re-contamination of the wafer W.

The configuration of the spray nozzle assembly 3310 including the first spray nozzle 3312 and the second spray nozzle 3314 of the cleaning fluid supply 3300 and the adjustment device 3320 may be applied in the same manner as the configuration of the spray nozzle assembly 1310 including the first spray nozzle 1312 and the second spray nozzle 1314 described above and the adjustment device 1320 described above, and therefore, a duplicate description thereof is omitted for conciseness.

In some example embodiments, the rotary table of the example illustrated in FIG. 9 may include the configuration of the guide protrusion described above.

The wafer cleaning device according to various example embodiments described above may effectively clean a wafer W and prevent re-contamination of the wafer W due to re-attachment of the cleaning fluid.

As set forth above, according to various example embodiments, a wafer cleaning device for effectively cleaning a wafer and preventing re-contamination of the wafer due to re-attachment of a cleaning fluid may be provided.

The various and advantageous features are not limited to the above description, and may be more easily understood in the course of describing the specific example embodiments.

While various example embodiments have been shown and described above with respect to the drawings, it will be apparent to those skilled in the art that modifications and variations could be made without departing from the scope of the present disclosure as defined by the appended claims.

What is claimed is:

1. A wafer cleaning device comprising:
a rotary table configured rotate around a rotation axis, and including a mounting surface having at least one disposition region that is spaced apart from the rotation axis, the mounting surface being disposed downwardly; and
a cleaning fluid supply disposed below and opposite to the mounting surface and supplying a cleaning fluid upwardly to the at least one disposition region.

2. The wafer cleaning device of claim 1, wherein the at least one disposition region comprises a plurality of disposition regions, and
the plurality of disposition regions are spaced apart from the rotation axis at equal intervals.

3. The wafer cleaning device of claim 2, wherein a circumferential interval between the plurality of disposition regions in a circumferential direction is the same.

4. The wafer cleaning device of claim 1, wherein each of the at least one disposition region includes a plurality of position limiting pins for position limiting and releasing the position limiting of a wafer.

5. The wafer cleaning device of claim 1, wherein the wafer cleaning device includes at least one chuck that is disposed respectively in the at least one disposition region and that has a holding surface for holding a wafer, and
wherein the holding surface includes a plurality of position limiting pins for limiting a position of the wafer.

6. The wafer cleaning device of claim 5, wherein the at least one chuck is an electrostatic chuck or a vacuum chuck.

7. The wafer cleaning device of claim 5, wherein the holding surface is disposed in a direction parallel to the mounting surface.

8. The wafer cleaning device of claim 5, wherein the holding surface is inclined at a certain angle with respect to a direction parallel to the mounting surface.

9. The wafer cleaning device of claim 1, wherein the mounting surface comprises a guide protrusion on an outer edge of the mounting surface, the guide protrusion guiding the cleaning fluid to flow downwardly from the mounting surface.

10. The wafer cleaning device of claim 9, wherein the guide protrusion is disposed in a ring shape in a circumferential direction on the outer edge of the mounting surface.

11. The wafer cleaning device of claim 10, wherein the guide protrusion has a protrusion height that gradually increases from the outer edge of the mounting surface in a radial direction of the rotary table.

12. The wafer cleaning device of claim 11, wherein the guide protrusion includes a guide surface having a curved shape in the radial direction of the rotary table.

13. The wafer cleaning device of claim 1, wherein the cleaning fluid supply comprises a plurality of spray nozzle assemblies disposed opposite to each of the at least one disposition region, the plurality of spray nozzle assemblies spraying the cleaning fluid toward the at least one disposition region.

14. The wafer cleaning device of claim 13, wherein the cleaning fluid supply comprises an angle adjustment device connected to each of the plurality of spray nozzle assemblies, the angle adjustment device adjusting a spraying angle of each of the plurality of spray nozzle assemblies.

15. The wafer cleaning device of claim 13, wherein each of the plurality of spray nozzle assemblies includes a plurality of spray nozzles arranged in a direction parallel to the mounting surface.

16. The wafer cleaning device of claim 13, wherein each of the plurality of spray nozzle assemblies includes at least one of a first spray nozzle for spraying a cleaning liquid or a second spray nozzle for spraying a cleaning gas.

17. The wafer cleaning device of claim 1, wherein the cleaning fluid is a cleaning liquid or a cleaning gas.

18. A wafer cleaning device comprising:
a rotary table configured to rotate around a rotation axis, and including a mounting surface that has a plurality of disposition regions that are spaced apart from the rotation axis, wherein the mounting surface is disposed downwardly;
a plurality of chucks disposed respectively in the plurality of disposition regions, each of the plurality of chucks including a holding surface configured to adsorb and hold a wafer and a plurality of position limiting pins disposed to be elevatable on the holding surface for position limiting or releasing the position limiting of an outer peripheral surface of the wafer; and
a cleaning fluid supply disposed below and opposite to the mounting surface and supplying a cleaning fluid upwardly to the plurality of disposition regions.

19. The wafer cleaning device of claim 18, wherein the holding surfaces of the plurality of chucks are disposed in a direction parallel to the mounting surface or are disposed to be inclined downwardly at an angle with respect to the direction parallel to the mounting surface outwardly of a radial direction of the rotary table.

20. A wafer cleaning device comprising:
a chamber including a processing space for processing a wafer;
a rotary shaft rotatably disposed above the processing space around a rotation axis;
a rotary driver connected to the rotary shaft and configured to rotate the rotary shaft;
a rotary table disposed below the rotary shaft, and including a mounting surface has a plurality of disposition regions that are spaced apart from the rotation axis, the mounting surface being disposed downwardly;
a cleaning fluid supply disposed below the processing space and supplying a cleaning fluid upwardly to the plurality of disposition regions; and
a discharge device that discharges the cleaning fluid within the processing space.
